(19) United States
(12) Patent Application Publication
(10) Pub. No.: US 2014/0057443 A1
(43) Pub. Date: Feb. 27, 2014

(54) PATTERN FORMING METHOD

(71) Applicant: KABUSHIKI KAISHA TOSHIBA, Tokyo (JP)

(72) Inventors: Hitoshi KUBOTA, Yokohama-Shi (JP); Katsutoshi Kobayashi, Tokyo (JP); Yusuke Sekiguchi, Yokkaichi-Shi (JP)

(73) Assignee: KABUSHIKI KAISHA TOSHIBA, Tokyo (JP)

(21) Appl. No.: 13/775,763

(22) Filed: Feb. 25, 2013

(30) Foreign Application Priority Data
Aug. 21, 2012 (JP) 2012-182454

(51) Int. Cl. H01L 21/308

(52) U.S. Cl. CPC H01L 21/308
USPC 438/703

(57) ABSTRACT

According to one embodiment, a pattern forming method includes forming a physical guide including a first predetermined pattern in a first region on a to-be-processed film, and a second predetermined pattern in a second region on the to-be-processed film, forming a block copolymer in the physical guide, forming a self-assembled phase including a first polymer portion and a second polymer portion by causing microphase separation of the block copolymer, removing the second polymer portion, and processing the to-be-processed film, with the physical guide and the first polymer portion serving as a mask. A pattern height of the first predetermined pattern is greater than a pattern height of the second predetermined pattern.

### CROSS REFERENCE TO RELATED APPLICATION

This application is based upon and claims benefit of priority from the Japanese Patent Application No. 2012-182454, filed on Aug. 21, 2012, the entire contents of which are incorporated herein by reference.

### FIELD

Embodiments described herein relate generally to a pattern forming method.

### BACKGROUND

Known lithography techniques to be used during procedures for manufacturing semiconductor elements include a double-patterning technique using ArF immersion exposure, EUV lithography, nanoimprint, and the like. As patterns have become smaller, those conventional lithography techniques entail various problems such as higher costs and lower throughputs.

Under such circumstances, applications of directed self-assembly (DSA) to the lithography techniques are expected. Directed self-assembly occurs through the spontaneous behavior of energy stabilization, and accordingly, can contribute to formation of patterns with high size precision. Particularly, by a technique utilizing microphase separation of a polymeric block copolymer, periodic structures that are of various shapes and of several to hundreds of nanometers can be formed through simple coating and annealing processes. Spheres, cylinders, lamellas, or the like can be formed depending on the composition ratio in the blocks of the polymeric block copolymer, and the sizes can vary depending on the molecular weight. In this manner, dot patterns, hole patterns, pillar patterns, line patterns, or the like of various sizes can be formed.

To form desired patterns over a wide area by using DSA, it is necessary to prepare guides for controlling the positions in which polymer phases are to be formed through directed self-assembly. As known guides, there have been physical guides (grapho-epitaxy) that have concave and convex structures and are used to form microphase separation patterns in the concave portions, and chemical guides (chemical-epitaxy) that are formed in a lower layer made of a DSA material and are used to control the formation positions of microphase separation patterns based on variations of the surface energy of the lower layer.

In a case where physical guides are used, when a block copolymer is applied in accordance with region with the higher pattern density among the guide patterns, the block copolymer overflows from the guide patterns in the region with the lower pattern density. As a result, desired phase separation patterns cannot be formed.

### BRIEF DESCRIPTION OF THE DRAWINGS

FIGS. 1A and 1B are cross-sectional process views for explaining a pattern forming method according to a first embodiment;

FIGS. 2A and 2B are cross-sectional process views subsequent to FIGS. 1A and 1B;

FIGS. 3A and 3B are cross-sectional process views subsequent to FIGS. 2A and 2B;

FIGS. 4A and 4B are cross-sectional process views subsequent to FIGS. 3A and 3B;

FIGS. 5A and 5B are cross-sectional process views subsequent to FIGS. 4A and 4B;

FIGS. 6A and 6B are cross-sectional process views subsequent to FIGS. 5A and 5B;

FIGS. 7A and 7B are diagrams for explaining a method of determining a film thickness of a resist film;

FIGS. 8A and 8B are diagrams for explaining a method of determining a film thickness of a resist film;

FIGS. 9A and 9B are cross-sectional process views for explaining a pattern forming method according to a second embodiment;

FIGS. 10A and 10B are cross-sectional process views subsequent to FIGS. 9A and 9B;

FIGS. 11A and 11B are cross-sectional process views subsequent to FIGS. 10A and 10B;

FIGS. 12A and 12B are cross-sectional process views subsequent to FIGS. 11A and 11B;

FIGS. 13A and 13B are cross-sectional process views subsequent to FIGS. 12A and 12B;

FIGS. 14A and 14B are cross-sectional process views subsequent to FIGS. 13A and 13B;

FIGS. 15A and 15B are cross-sectional process views for explaining a pattern forming method according to a third embodiment;

FIGS. 16A and 16B are cross-sectional process views subsequent to FIGS. 15A and 15B;

FIGS. 17A and 17B are cross-sectional process views subsequent to FIGS. 16A and 16B;

FIGS. 18A and 18B are cross-sectional process views subsequent to FIGS. 17A and 17B;

FIGS. 19A and 19B are cross-sectional process views subsequent to FIGS. 18A and 18B;

FIGS. 20A and 20B are cross-sectional process views subsequent to FIGS. 19A and 19B;

FIGS. 21A and 21B are cross-sectional process views for explaining a pattern forming method according to a fourth embodiment;

FIGS. 22A and 22B are cross-sectional process views subsequent to FIGS. 21A and 21B;

FIGS. 23A and 23B are cross-sectional process views subsequent to FIGS. 22A and 22B;

FIGS. 24A and 24B are diagrams showing a template according to a fifth embodiment;

FIGS. 25A and 25B are cross-sectional process views for explaining a pattern forming method according to the fifth embodiment;

FIGS. 26A and 26B are cross-sectional process views subsequent to FIGS. 25A and 25B;

FIGS. 27A and 27B are cross-sectional process views subsequent to FIGS. 26A and 26B;

FIGS. 28A and 28B are cross-sectional process views subsequent to FIGS. 27A and 27B;

FIGS. 29A and 29B are cross-sectional process views subsequent to FIGS. 28A and 28B; and

FIGS. 30A and 30B are cross-sectional process views subsequent to FIGS. 29A and 29B.

### DETAILED DESCRIPTION

According to one embodiment, a pattern forming method includes forming a physical guide including a first predetermined pattern in a first region on a to-be-processed film, and a second predetermined pattern in a second region on the to-be-processed film, forming a block copolymer in the physical guide, forming a self-assembled phase including a first polymer portion and a second polymer portion by causing microphase separation of the block copolymer, removing the second polymer portion, and processing the to-be-processed film, with the physical guide and the first polymer portion serving as a mask. A pattern height of the first predetermined pattern is greater than a pattern height of the second predetermined pattern.

Embodiments will now be explained with reference to the accompanying drawings.

### First Embodiment

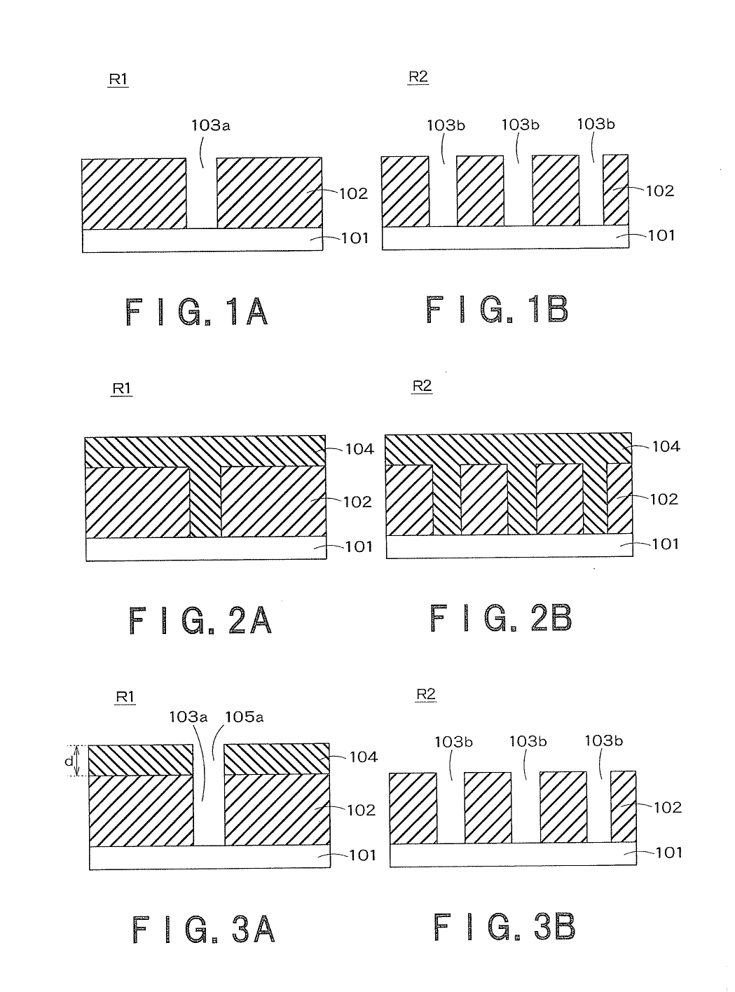

Referring now to FIGS. 1A and 1B through 6A and 6B, a pattern forming method according to a first embodiment is described.

First, as shown in FIGS. 1A and 1B, a resist film 102 is rotationally applied onto a to-be-processed film 101, and exposure and development are performed by an ArF immersion excimer laser with an exposure amount of 20 mJ/cm², to form circular hole patterns 103a and 103b in the resist film 102. The to-be-processed film 101 is an oxide film, for example.

The hole patterns 103a and 103b function as physical guide layers at the time of microphase separation of a block copolymer formed in a later procedure. The hole patterns 103a are formed in an isolated pattern region R1 in which the number of hole patterns is small, and the hole patterns 103b are formed in a dense pattern region R2 in which the number of hole patterns is large.

It can be said that the dense pattern region R2 is a region with a lower coverage with the resist film 102 (or a region with a higher aperture ratio) than the isolated pattern region R1. In a case where a pattern transferred to the to-be-processed film 101 is a reference pattern, the dense pattern region R2 can be a region with a higher pattern density than the isolated pattern region R1. FIGS. 1A, 2A, 3A, 4A, 5A, and 6A are cross-sectional views of the isolated pattern region R1. FIGS. 1B, 2B, 3B, 4B, 5B, and 6B are cross-sectional views of the dense pattern region R2.

Before the resist film 102 is applied, an anti-reflection coating or the like may be formed on the to-be-processed film 101.

As shown in FIGS. 2A and 2B, a resist film 104 is rotationally applied onto the resist film 102. The resist film 104 is also buried in the hole patterns 103a and 103b.

As shown in FIGS. 3A and 3B, exposure and development are then performed by an ArF immersion excimer laser with an exposure amount of 20 mJ/cm², to form circular hole patterns 105a in the resist film 104. The hole patterns 105a are formed in the same positions as the hole patterns 103a, and have the same size as the hole patterns 103a. With deviations from the hole patterns 103a being taken into consideration, the hole patterns 105a may be made slightly larger than the hole patterns 103a.

After the exposure and development, the portion of the resist film 104 in the dense pattern region R2 is removed. That is, in a case where the resist film 104 is of a positive type, the entire dense pattern region R2 is exposed. In a case where the resist film 104 is of a negative type, the entire dense pattern region R2 is blocked from being exposed to light.

With this arrangement, physical guides among which the pattern height of the guide patterns in the isolated pattern region R1 is greater than the pattern height of the guide patterns in the dense pattern region R2 can be formed. The film thickness d of the resist film 104 formed on the resist film 102 will be described later.

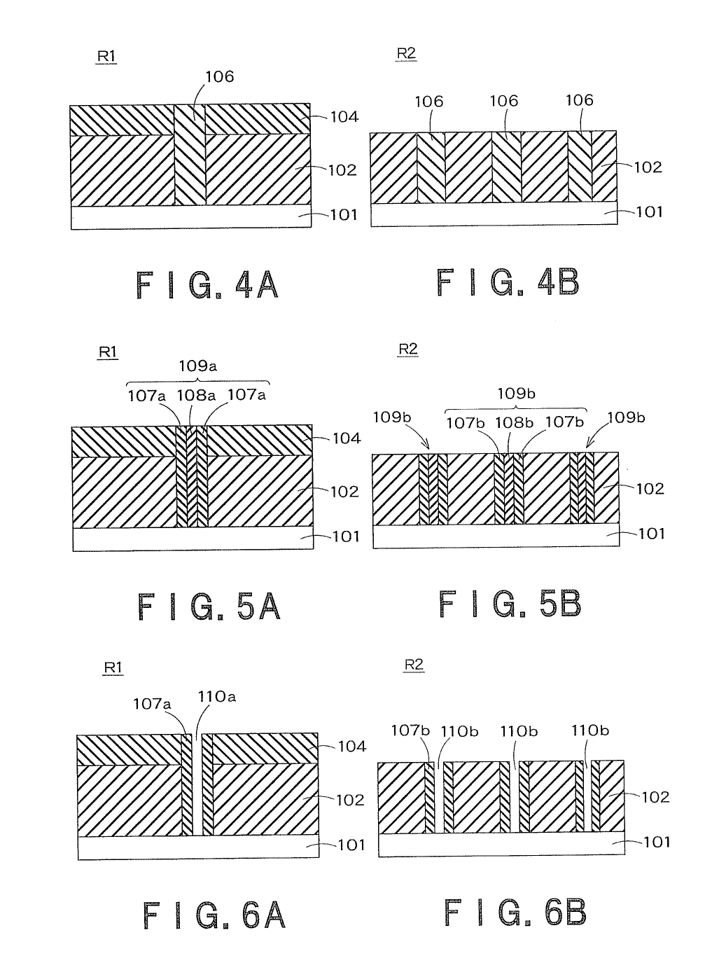

As shown in FIGS. 4A and 4B, a block copolymer 106 is then applied. A block copolymer (PS-b-PDMS) of polystyrene (PS) and polydimethylsiloxane (PDMS) is prepared, and a propylene glycol monomethyl ether acetate (PGMEA) solution containing the block copolymer at a concentration of 1.0 wt % is rotationally applied. As a result, the block copolymer 106 is buried in the hole patterns (the hole patterns 105a, 103a, and 103b) of the physical guides.

The isolated pattern region R1 accommodates a smaller number of hole patterns than the dense pattern region R2, but has a greater pattern height than the dense pattern region R2. Therefore, in both the isolated pattern region R1 and the dense pattern region R2, the block copolymer 106 can be appropriately buried in the hole patterns of the physical guides, without an overflow of the block copolymer 106.

As shown in FIGS. 5A and 5B, a hot plate (not shown) is used to perform heating at 110° C. for 90 seconds, and further perform heating at 220° C. for 3 minutes in a nitrogen atmosphere. As a result, microphase separation occurs in the block copolymer 106, to form self-assembled phases 109a and 109b including first polymer portions 107a and 107b including first polymer block chains, and second polymer portions 108a and 108b including second polymer block chains. For example, the first polymer portions 107a and 107b containing PDMS are formed (segregated) at the sidewall portions of the hole patterns, and the second polymer portions 108a and 108b containing PS are formed at the center portions of the hole patterns.

As shown in FIGS. 6A and 6B, oxygen RIE (reactive ion etching) is then performed to leave the first polymer portions 107a and 107b, and selectively remove the second polymer portions 108a and 108b. In this manner, hole patterns 110a and 110b are formed. The hole patterns 110a and 110b are equivalent to portions formed by contracting the hole patterns 103a and 103b.

After that, the to-be-processed film 101 is processed, with the remaining first polymer portions 107a and 107b and the physical guides (the resist films 102 and 104) serving as masks. The pattern shapes of the hole patterns 110a and 110b are transferred to the processed film 101.

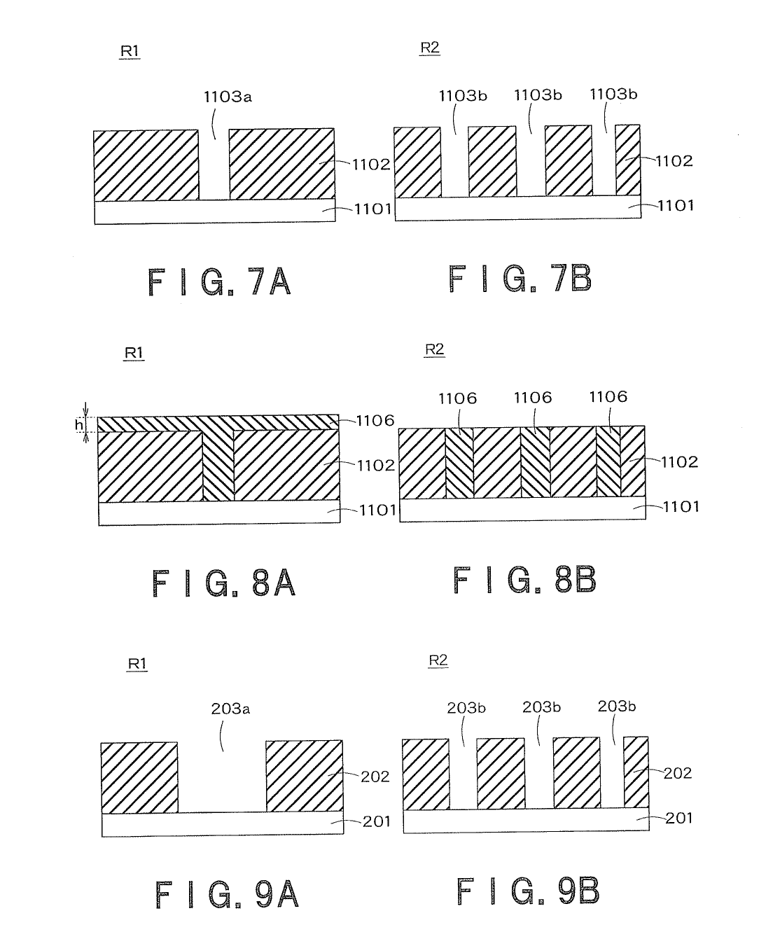

Next, the film thickness d of the resist film 104 is described. Before the film thickness d of the resist film 104 is determined, a resist film 1102 is rotationally applied onto a to-be-processed film 1101, and exposure and development are performed by an ArF immersion excimer laser with an exposure amount of 20 ml/cm², to form circular hole patterns 1103a and 1103b in the resist film 1102, as shown in FIGS. 7A and 7B. This procedure is the same as that illustrated in FIGS. 1A and 1B, and the film thickness of the resist film 1102 and the sizes of the hole patterns 1103a and 1103b are the same as the film thickness of the resist film 102 and the sizes of the hole patterns 103a and 103b, respectively. The hole patterns 1103a are formed in the isolated pattern region R1, and the hole patterns 1103b are formed in the dense pattern region R2.

As shown in FIGS. 8A and 8B, a block copolymer 1106 is then applied. The block copolymer 1106 used here is the same as the block copolymer 106. The amount of the block copolymer 1106 applied here is such an amount as to fill up the hole patterns 1103b in the dense pattern region R2. At this point, the block copolymer 1106 overflows from the hole patterns 1103a in the isolated pattern region R1 with the smaller number of hole patterns. The cross-section height of the overflowing block copolymer 1106 is represented by h.

The film thickness d of the resist film 104 is determined so as to prevent the overflow of the block copolymer 1106. For example, the film thickness d is determined to be d=(the area of the isolated pattern region R1)×h/(the total pattern area of the hole patterns 103a (1103a) formed in the isolated pattern region R1).

In this embodiment, in a case where the thickness of the physical guides in the isolated pattern region R1 is made greater (or the height of the guide patterns is made greater) than that in the dense pattern region R2 by the amount equivalent to the film thickness d determined in the above described manner, and such an amount of block copolymer as to fill up the hole patterns 103b in the dense pattern region R2 is applied, the block copolymer can be appropriately buried in the guide patterns (the hole patterns 103a) and form desired phase separation patterns in the isolated pattern region R1, without an overflow of the block copolymer from the guide patterns.

As described above, according to this embodiment, desired phase separation patterns can be formed, regardless of density variations of the guide patterns of the physical guides.

Although the first polymer portions 107a and 107b are formed at the sidewall portions of the hole patterns 105a, 103a, and 103b in the above described embodiment, the first polymer portions 107a and 107b may be formed at the sidewall portions and the bottom portions of the hole patterns 105a, 103a, and 103b.

Meanwhile, the application of the resist film 104 prevents the resist film 102 from dissolving. In order to do that, it is preferable to use different materials from the resist film 102 and the resist film 104.

### Second Embodiment

Referring now to FIGS. 9A and 9B through 14A and 14B, a pattern forming method according to a second embodiment is described.

First, as shown in FIGS. 9A and 9B, a resist film 202 is rotationally applied onto a to-be-processed film 201, and exposure and development are performed by an ArF immersion excimer laser with an exposure amount of 20 mJ/cm², to form circular hole patterns 203a and 203b in the resist film 202. For example, the to-be-processed film 201 is an oxide film.

The hole patterns 203a are formed in an isolated pattern region R1 in which the number of hole patterns is small, and the hole patterns 203b are formed in a dense pattern region R2 in which the number of hole patterns is large. The hole patterns 203b function as physical guide layers at the time of microphase separation of a block copolymer formed in a later procedure.

In a case where a pattern transferred to the to-be-processed film 201 is a reference pattern, the dense pattern region R2 can be a region with a higher pattern density than the isolated pattern region R1, as in the above described first embodiment. FIGS. 9A, 10A, 11A, 12A, 13A, and 14A are cross-sectional views of the isolated pattern region R1. FIGS. 9B, 10B, 11B, 12B, 13B, and 14B are cross-sectional views of the dense pattern region R2.

Before the resist film 202 is applied, an anti-reflection coating or the like may be formed on the to-be-processed film 201.

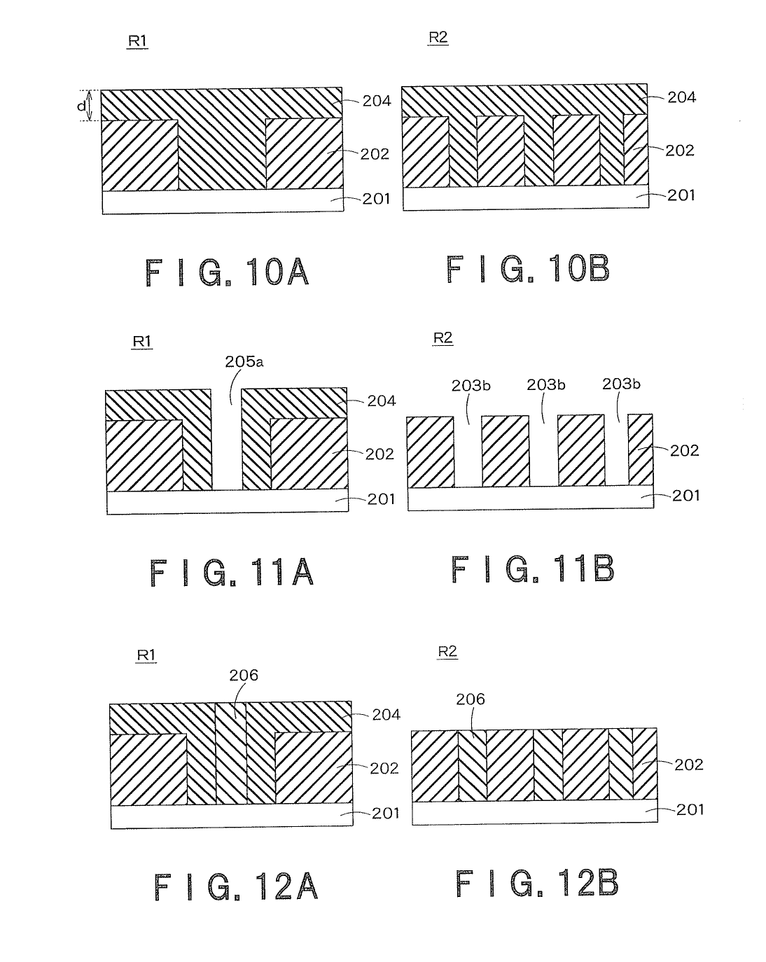

As shown in FIGS. 10A and 10B, a resist film 204 is rotationally applied onto the resist film 202. The resist film 204 is also buried in the hole patterns 203a and 203b. The film thickness d of the resist film 204 is the same as that in the first embodiment.

As shown in FIGS. 11A and 11B, exposure and development are then performed by an ArF immersion excimer laser with an exposure amount of 20 mJ/cm², to form circular hole patterns 205a in the resist film 204. The hole patterns 205a are smaller than the hole patterns 203a, and are formed inside the hole patterns 203a. After the exposure and development, the portion of the resist film 204 in the dense pattern region R2 is removed. That is, in a case where the resist film 204 is of a positive type, the entire dense pattern region R2 is exposed. In a case where the resist film 204 is of a negative type, the entire dense pattern region R2 is blocked from being exposed to light.

The hole patterns 205a function as physical guide layers at the time of microphase separation of the block copolymer formed in a later procedure.

With this arrangement, physical guides among which the pattern height of the guide patterns in the isolated pattern region R1 is greater than the pattern height of the guide patterns in the dense pattern region R2 can be formed.

As shown in FIGS. 12A and 12B, a block copolymer 206 is then applied. A block copolymer (PS-b-PDMS) of polystyrene (PS) and polydimethylsiloxane (PDMS) is prepared, and a propylene glycol monomethyl ether acetate (PGMEA) solution containing the block copolymer at a concentration of 1.0 wt % is rotationally applied. As a result, the block copolymer 206 is buried in the hole patterns (the hole patterns 205a and 203b) of the physical guides.

The isolated pattern region R1 accommodates a smaller number of hole patterns than the dense pattern region R2, but has a greater pattern height than the dense pattern region R2. Therefore, in both the isolated pattern region R1 and the dense pattern region R2, the block copolymer 206 can be appropriately buried in the hole patterns of the physical guides, without an overflow of the block copolymer 206.

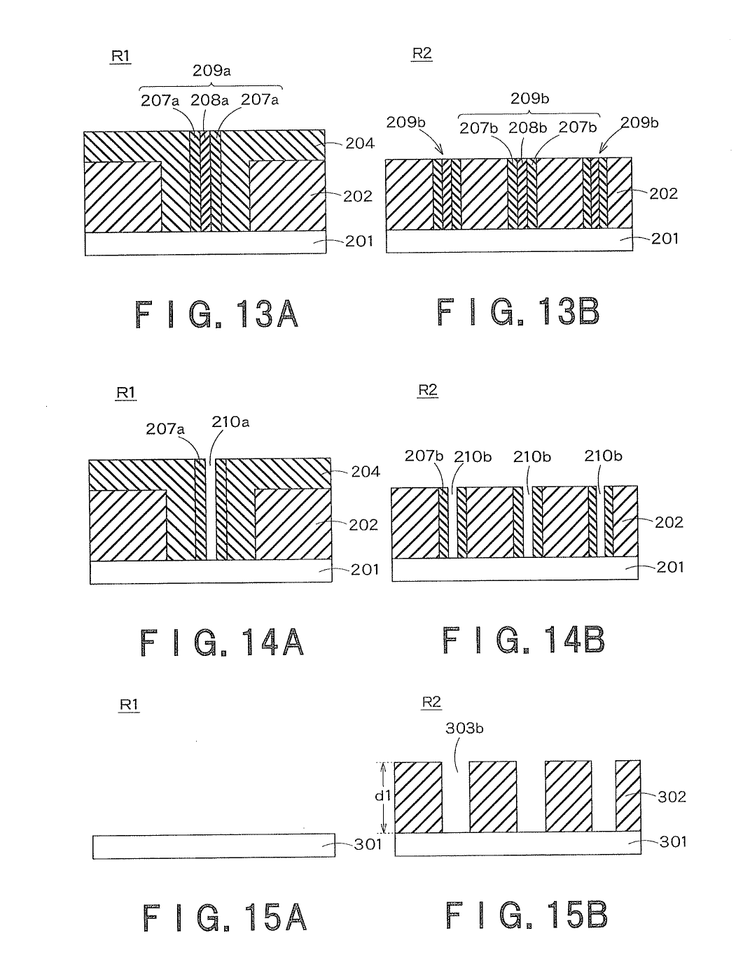

As shown in FIGS. 13A and 13B, a hot plate (not shown) is used to perform heating at 110° C. for 90 seconds, and further perform heating at 220° C. for 3 minutes in a nitrogen atmosphere. As a result, microphase separation occurs in the block copolymer 206, to form self-assembled phases 209a and 209b including first polymer portions 207a and 207b including first polymer block chains, and second polymer portions 208a and 208b including second polymer block chains. For example, the first polymer portions 207a and 207b containing PDMS are formed (segregated) at the sidewall portions of the hole patterns, and the second polymer portions 208a and 208b containing PS are formed at the center portions of the hole patterns.

As shown in FIGS. 14A and 14B, oxygen RIE (reactive ion etching) is then performed to leave the first polymer portions 207a and 207b, and selectively remove the second polymer portions 208a and 208b. In this manner, hole patterns 210a and 210b are formed. The hole patterns 210a and 210b are equivalent to portions formed by contracting the hole patterns 205a and 203b.

After that, the to-be-processed film 201 is processed, with the remaining first polymer portions 207a and 207b and the physical guides (the resist films 202 and 204) serving as masks. The pattern shapes of the hole patterns 210a and 210b are transferred to the processed film 201.

In this embodiment, in a case where the thickness of the physical guides in the isolated pattern region R1 is made greater (or the height of the guide patterns is made greater) than that in the dense pattern region R2, and such an amount of block copolymer as to fill up the hole patterns 203b in the dense pattern region R2 is applied, desired phase separation patterns can be formed, without an overflow of the block copolymer from the guide patterns (the hole patterns 205a) in the isolated pattern region R1.

As described above, according to this embodiment, desired phase separation patterns can be formed, regardless of density variations of the guide patterns of the physical guides.

Also, in the above described first embodiment, the hole patterns 105a need to be formed in the same positions as the hole patterns 103a, and high alignment accuracy is required. In this embodiment, on the other hand, the hole patterns 205a are simply formed in the larger hole patterns 203a, and high alignment accuracy is not required.

### Third Embodiment

Referring now to FIGS. 15A and 15B through 20A and 20B, a pattern forming method according to a third embodiment is described.

First, as shown in FIGS. 15A and 15B, a resist film 302 is rotationally applied onto a to-be-processed film 301, and exposure and development are performed by an ArF immersion excimer laser with an exposure amount of 20 mJ/cm², to form circular hole patterns 303b in the resist film 302 having a film thickness d1. For example, the to-be-processed film 301 is an oxide film.

The hole patterns 303b are formed in a dense pattern region R2 in which the number of hole patterns is large. The hole patterns 303b function as physical guide layers at the time of microphase separation of a block copolymer formed in a later procedure.

After the exposure and development, the portion of the resist film 302 in an isolated pattern region R1 is removed. That is, in a case where the resist film 302 is of a positive type, the entire isolated pattern region R1 is exposed. In a case where the resist film 302 is of a negative type, the entire isolated pattern region R1 is blocked from being exposed to light.

In a case where a pattern transferred to the to-be-processed film 301 is a reference pattern, the dense pattern region R2 can be a region with a higher pattern density than the isolated pattern region R1, as in the above described first embodiment. FIGS. 15A, 16A, 17A, 18A, 19A, and 20A are cross-sectional views of the isolated pattern region R1. FIGS. 15B, 16B, 17B, 18B, 19B, and 20B are cross-sectional views of the dense pattern region R2.

Before the resist film 302 is applied, an anti-reflection coating or the like may be formed on the to-be-processed film 301.

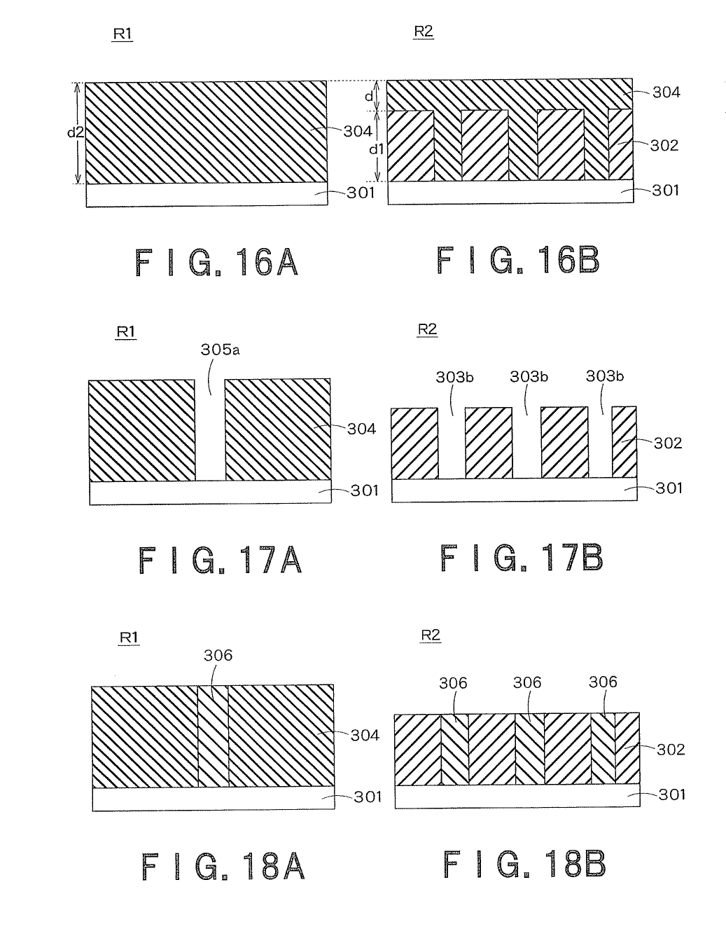

As shown in FIGS. 16A and 16B, a resist film 304 is rotationally applied onto the to-be-processed film 301. The film thickness d2 of the resist film 304 is greater than the film thickness d1 of the resist film 302, and the difference between those film thicknesses is equal to the film thickness d in the above described first embodiment. That is, d2−d1=d.

As shown in FIGS. 17A and 17B, exposure and development are then performed by an ArF immersion excimer laser with an exposure amount of 20 mJ/cm², to form circular hole patterns 305a in the resist film 304 in the isolated pattern region R1. After the exposure and development, the portion of the resist film 304 in the dense pattern region R2 is removed. That is, in a case where the resist film 304 is of a positive type, the entire dense pattern region R2 is exposed. In a case where the resist film 304 is of a negative type, the entire dense pattern region R2 is blocked from being exposed to light.

The hole patterns 305a function as physical guide layers at the time of microphase separation of the block copolymer formed in a later procedure.

With this arrangement, physical guides among which the pattern height of the guide patterns in the isolated pattern region R1 is greater than the pattern height of the guide patterns in the dense pattern region R2 can be formed.

As shown in FIGS. 18A and 18B, a block copolymer 306 is then applied. A block copolymer (PS-b-PDMS) of polystyrene (PS) and polydimethylsiloxane (PDMS) is prepared, and a propylene glycol monomethyl ether acetate (PGMEA) solution containing the block copolymer at a concentration of 1.0 wt % is rotationally applied. As a result, the block copolymer 306 is buried in the hole patterns (the hole patterns 305a and 303b) of the physical guides.

The isolated pattern region R1 accommodates a smaller number of hole patterns than the dense pattern region R2, but has a greater pattern height than the dense pattern region R2. Therefore, in both the isolated pattern region R1 and the dense pattern region R2, the block copolymer 306 can be appropriately buried in the hole patterns of the physical guides, without an overflow of the block copolymer 306.

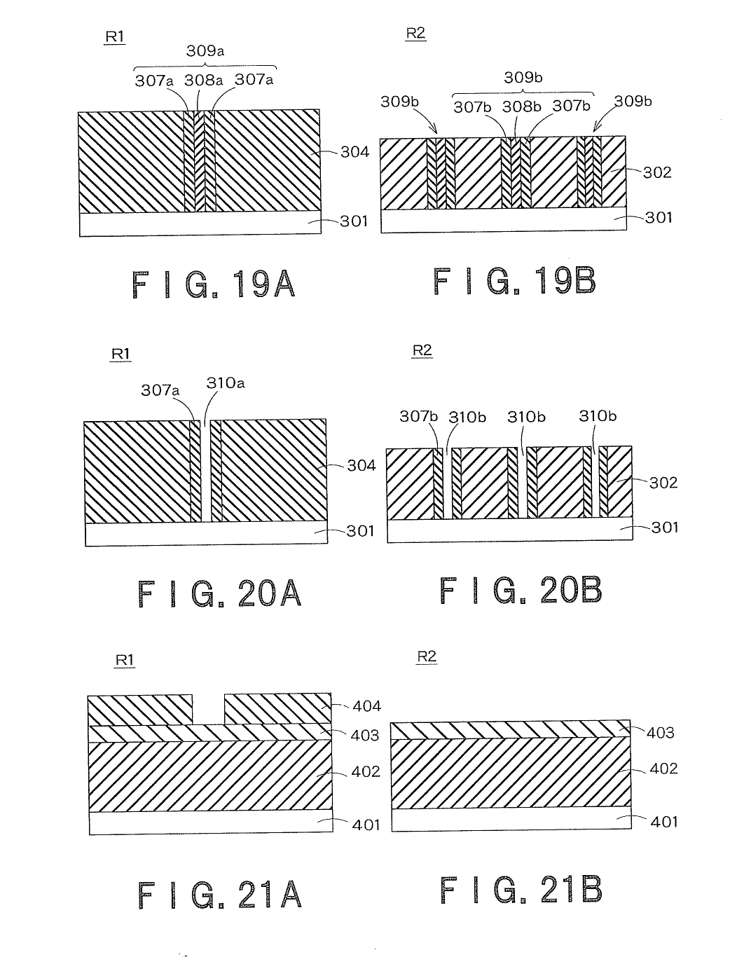

As shown in FIGS. 19A and 19B, a hot plate (not shown) is used to perform heating at 110° C. for 90 seconds, and further perform heating at 220° C. for 3 minutes in a nitrogen atmosphere. As a result, microphase separation occurs in the block copolymer 306, to form self-assembled phases 309a and 309b including first polymer portions 307a and 307b including first polymer block chains, and second polymer portions 308a and 308b including second polymer block chains. For example, the first polymer portions 307a and 307b containing PDMS are formed (segregated) at the sidewall portions of the hole patterns, and the second polymer portions 308a and 308b containing PS are formed at the center portions of the hole patterns.

As shown in FIGS. 20A and 20B, oxygen RIE (reactive ion etching) is then performed to leave the first polymer portions 307a and 307b, and selectively remove the second polymer portions 308a and 308b. In this manner, hole patterns 310a and 310b are formed. The hole patterns 310a and 310b are equivalent to portions formed by contracting the hole patterns 305a and 303b.

After that, the to-be-processed film 301 is processed, with the remaining first polymer portions 307a and 307b and the physical guides (the resist films 302 and 304) serving as masks. The pattern shapes of the hole patterns 310a and 310b are transferred to the processed film 301.

In this embodiment, in a case where the thickness of the physical guides in the isolated pattern region R1 is made greater (or the height of the guide patterns is made greater) than that in the dense pattern region R2, and such an amount of block copolymer as to fill up the hole patterns 303b in the dense pattern region R2 is applied, desired phase separation patterns can be formed, without an overflow of the block copolymer from the guide patterns (the hole patterns 305a) in the isolated region R1.

As described above, according to this embodiment, desired phase separation patterns can be formed, regardless of density variations of the guide patterns of the physical guides.

In the above described third embodiment, after the physical guides in the dense pattern region R2 (or the resist film 302 including the hole patterns 303b) are formed, the physical guides in the isolated pattern region R1 (or the resist film 304 including the hole patterns 305a) are formed. However, the sequential order may be reversed. That is, the physical guides in the dense pattern region R2 (or the resist film 302 including the hole patterns 303b) may be formed after the physical guides in the isolated pattern region R1 (or the resist film 304 including the hole patterns 305a) are formed.

### Fourth Embodiment

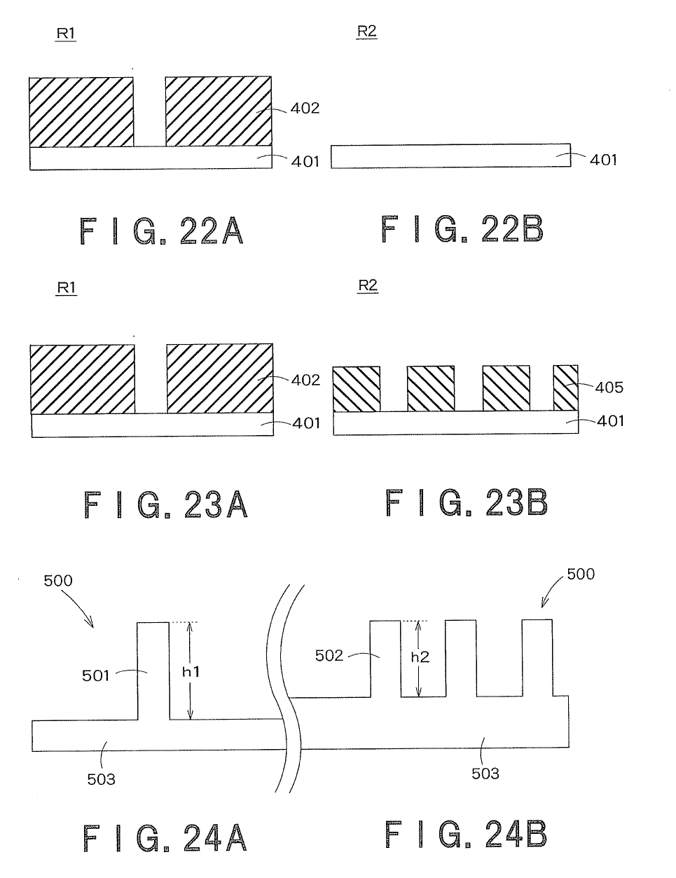

A physical guide in the isolated pattern region R1 (or the dense pattern region R2) may be formed by using a material other than resist. For example, firstly, as shown in FIGS. 21A and 21B, an underlayer film (or an anti-reflection coating) 402 is formed on a to-be-processed film 401. Next, an intermediate film 403 and a first resist pattern 404 are formed successively on the underlayer film 402 in the isolated pattern region R1. Next, the intermediate film 403 and the underlayer film 402 are processed, with the first resist pattern 404 serving as a mask. The underlayer film 402 in the dense pattern region R2 is removed. As shown in FIGS. 22A and 22B, a first physical guide in the isolated pattern region R1 is formed by removing the first resist pattern 404 and the intermediate film 403.

After that, a resist film is applied onto the to-be-processed film 401. The thickness of the resist film is less than the thickness of the first physical guide. Then, as shown in FIGS. 23A and 23B, a second resist pattern 405 is formed in the dense pattern region R2 through lithography processes. The second resist pattern 405 becomes a second physical guide in the dense pattern region R2.

With this arrangement, physical guides among which the pattern height of the guide patterns in the isolated pattern region R1 is greater than the pattern height of the guide patterns in the dense pattern region R2 can be formed.

Subsequent processes are similar to processes in the above first to third embodiments. Specifically, a block copolymer is formed in the physical guide, and a self-assembled phase including a first polymer portion and a second polymer portion is formed by causing microphase separation of the block copolymer. Then, the second polymer portion is selectively removed, and the to-be-processed film is processed with the physical guide and the first polymer portion serving as a mask.

### Fifth Embodiment

In the above described first through third embodiments, physical guides having different heights in the isolated pattern region R1 and the dense pattern region R2 are formed through lithography processes. However, those physical guides may be formed through an imprint process.

First, as shown in FIGS. 24A and 24B, a template 500 having a surface in which concave and convex patterns corresponding to guide patterns of physical guides are formed is prepared. The template 500 includes convex patterns 501 corresponding to guide patterns in an isolated pattern region as shown in FIG. 24A, and convex patterns 502 corresponding to guide patterns in a dense pattern region as shown in FIG. 24B. The height h1 of the convex patterns 501 is greater than the height h2 of the convex patterns 502, and the difference between those heights is equal to the film thickness d in the above described first embodiment. That is, h1−h2=d.

In other words, the base portion 503 of the template 500 is thinner in the region corresponding to the isolated pattern region than in the region corresponding to the dense pattern region, and the difference in thickness is equal to the film thickness d in the above described first embodiment.

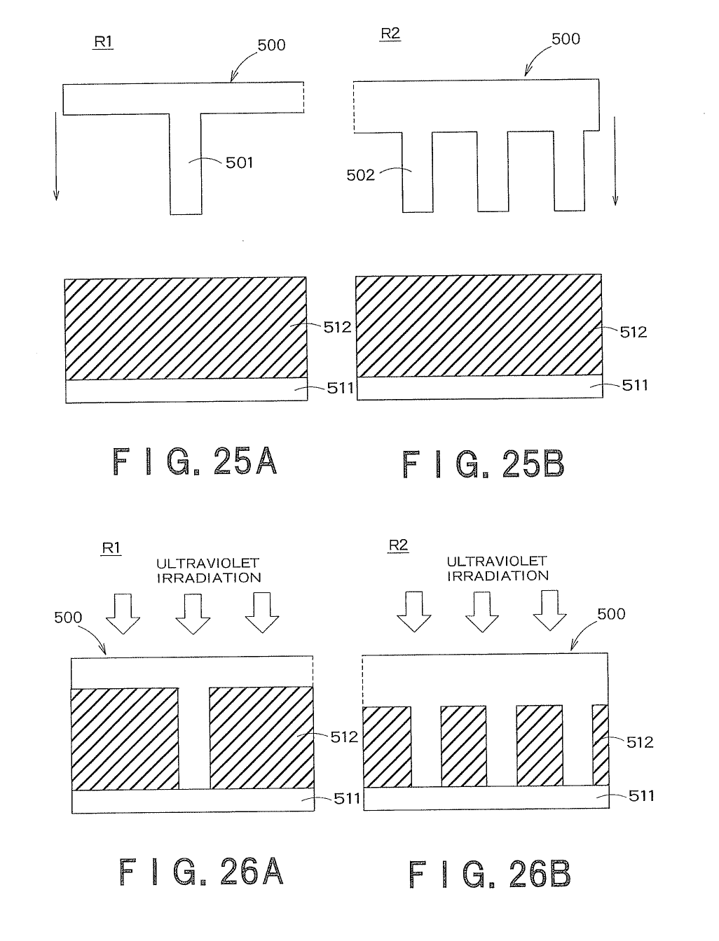

As shown in FIGS. 25A and 25B, an imprint material 512 is then applied onto the surface of a to-be-processed film 511. The imprint material 512 is a photocurable organic material such as acrylic monomer. The concave and convex pattern surface of the template 500 is then brought into contact with the applied imprint material 512. The liquid imprint material 512 flows into the concave and convex patterns of the template 500.

As shown in FIGS. 26A and 26B, after the concave and convex patterns are filled with the imprint material 512, ultraviolet rays are emitted from the back surface side of the template 500 (from the top in the drawings). In this manner, the imprint material 512 is cured.

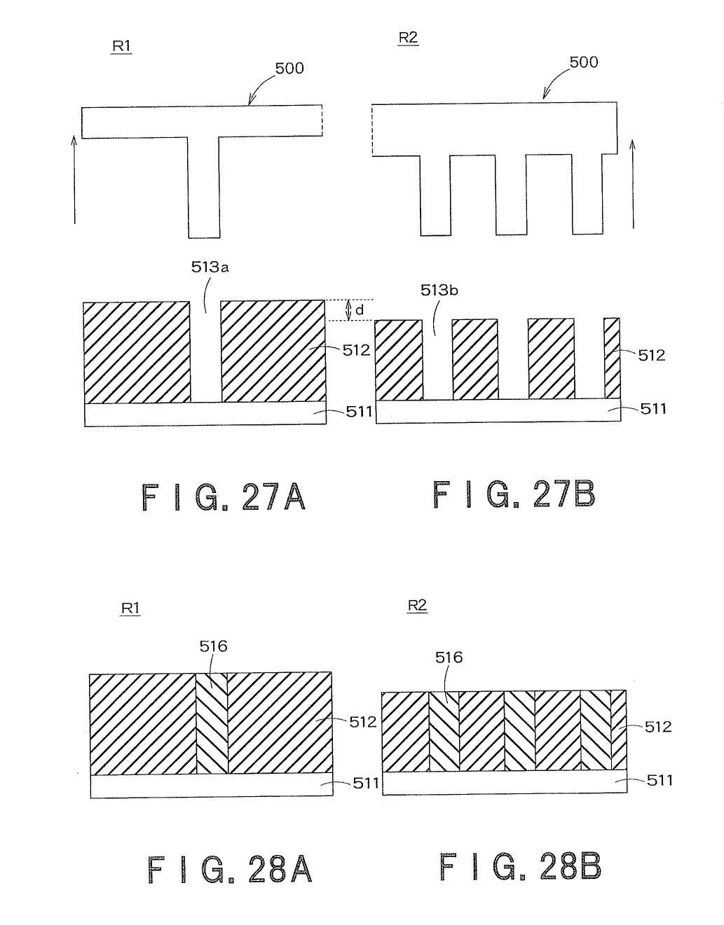

As shown in FIGS. 27A and 27B, the template 500 is then released from the cured imprint material 512. As a result, hole patterns 513a are formed in the isolated pattern region R1 of the imprint material 512, and hole patterns 513b are formed in the dense pattern region R2. The film thickness of the cured imprint material 512 is greater in the isolated pattern region R1 than in the dense pattern region R2, and the difference in film thickness is equal to the film thickness d in the above described first embodiment.

With this arrangement, physical guides among which the pattern height of the guide patterns in the isolated pattern region R1 is greater than the pattern height of the guide patterns in the dense pattern region R2 can be formed.

As shown in FIGS. 28A and 28B, a block copolymer 516 is then applied. A block copolymer (PS-b-PDMS) of polystyrene (PS) and polydimethylsiloxane (PDMS) is prepared, and a propylene glycol monomethyl ether acetate (PGMEA) solution containing the block copolymer at a concentration of 1.0 wt % is rotationally applied. As a result, the block copolymer 516 is buried in the hole patterns (the hole patterns 513a and 513b) of the physical guides.

The isolated pattern region R1 accommodates a smaller number of hole patterns than the dense pattern region R2, but has a greater pattern height than the dense pattern region R2. Therefore, in both the isolated pattern region R1 and the dense pattern region R2, the block copolymer 516 can be appropriately buried in the hole patterns of the physical guides, without an overflow of the block copolymer 516.

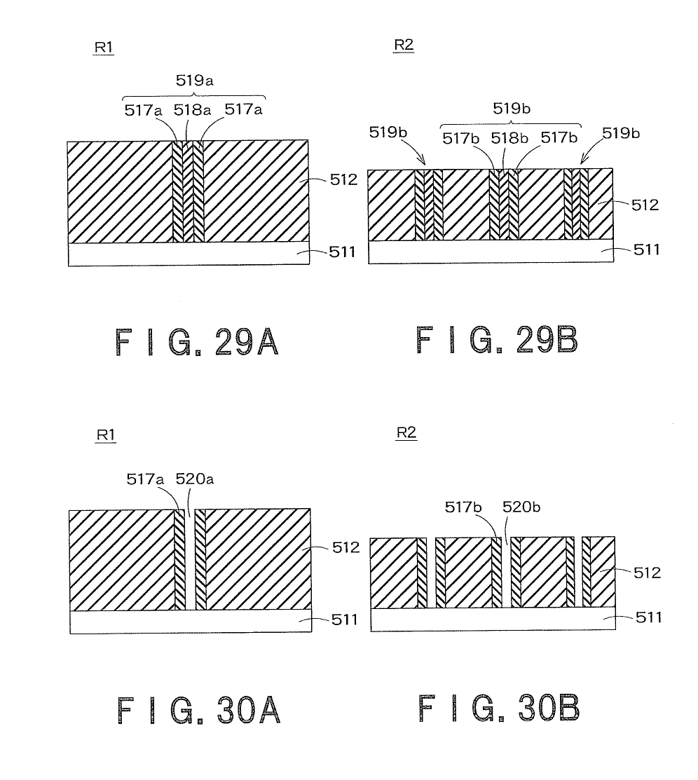

As shown in FIGS. 29A and 29B, a hot plate (not shown) is used to perform heating at 110° C. for 90 seconds, and further perform heating at 220° C. for 3 minutes in a nitrogen atmosphere. As a result, microphase separation occurs in the block copolymer 516, to form self-assembled phases 519a and 519b including first polymer portions 517a and 517b including first polymer block chains, and second polymer portions 518a and 518b including second polymer block chains. For example, the first polymer portions 517a and 517b containing PDMS are formed (segregated) at the sidewall portions of the hole patterns, and the second polymer portions 518a and 518b containing PS are formed at the center portions of the hole patterns.

As shown in FIGS. 30A and 30B, oxygen RIE (reactive ion etching) is then performed to leave the first polymer portions 517a and 517b, and selectively remove the second polymer portions 518a and 518b. In this manner, hole patterns 520a and 520b are formed. The hole patterns 520a and 520b are equivalent to portions formed by contracting the hole patterns 513a and 513b.

After that, the to-be-processed film 511 is processed, with the remaining first polymer portions 517a and 517b and the physical guides (the cured imprint material 512) serving as masks. The pattern shapes of the hole patterns 520a and 520b are transferred to the processed film 511.

In this embodiment, physical guides that are thicker in the isolated pattern region R1 than in the dense pattern region R2 are formed through an imprint process. Even in a case where such an amount of block copolymer as to fill up the hole patterns 513b in the dense pattern region R2 is applied, desired phase separation patterns can be formed, without an overflow of the block copolymer from the guide patterns (the hole patterns 513a) in the isolated pattern region R1.

As described above, according to this embodiment, desired phase separation patterns can be formed, regardless of density variations of the guide patterns of the physical guides.

Although hole patterns are formed in the above described first through fifth embodiments, line patterns may be formed instead. In that case, the physical guides have square shapes, and a material in which lamellar microphase separation occurs is used as the block copolymer.

In the above described embodiments, the entire region is divided into the two regions of the isolated pattern region R1 and the dense pattern region R2 based on the pattern density of guide patterns, and the thicknesses of the physical guides vary between the respective regions. However, the entire region may be divided into three or more regions. In that case, the physical guide thickness is greater in a region with a lower pattern density.

In the above described embodiments, optical lithography technique such as ArF dry exposure, ArF immersion exposure, and EUV lithography may be used.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A pattern forming method comprising:
forming a physical guide including a first predetermined pattern in a first region on a to-be-processed film, and a second predetermined pattern in a second region on the to-be-processed film;
forming a block copolymer in the physical guide;
forming a self-assembled phase including a first polymer portion and a second polymer portion by causing microphase separation of the block copolymer;
removing the second polymer portion; and
processing the to-be-processed film, with the physical guide and the first polymer portion serving as a mask,
wherein a pattern height of the first predetermined pattern is greater than a pattern height of the second predetermined pattern.

2. The pattern forming method according to claim 1, wherein the forming the physical guide comprises:
forming a first resist film on the to-be-processed film;
forming a pattern corresponding to the first predetermined pattern in the first resist film in the first region, and forming the second predetermined pattern in the first resist film in the second region;
forming a second resist film on the first resist film; and
removing the second resist film in the second region, and forming a pattern corresponding to the first predetermined pattern in the second resist film in the first region.

3. The pattern forming method according to claim 2, wherein
a hole pattern is formed in the first resist film in the first region;
the second resist film is formed to fill the hole pattern; and
the first predetermined pattern is formed in the second resist film in the hole pattern.

4. The pattern forming method according to claim 2, wherein
a first hole pattern is formed in the first resist film in the first region;
the second resist film is formed to fill the first hole pattern; and
a second hole pattern is formed in the second resist film to remove the second resist film buried in the first hole pattern.

5. The pattern forming method according to claim 4, wherein the first hole pattern has the same pattern size and the same pattern formation position as those in the second hole pattern.

6. The pattern forming method according to claim 2, wherein
a line pattern is formed in the first resist film in the first region;
the second resist film is formed to fill the line pattern; and
the first predetermined pattern is formed in the second resist film in the line pattern.

7. The pattern forming method according to claim 2, wherein
a first line pattern is formed in the first resist film in the first region;
the second resist film is formed to fill the first line pattern; and
a second line pattern is formed in the second resist film to remove the second resist film buried in the first line pattern.

8. The pattern forming method according to claim 7, wherein the first line pattern has the same pattern size and the same pattern formation position as those in the second line pattern.

9. The pattern forming method according to claim 2, wherein a material of the first resist film differs from a material of the second resist film.

10. The pattern forming method according to claim 1, wherein
the physical guide comprises:
a first resist film including the first predetermined pattern; and
a second resist film including the second predetermined pattern, and
a film thickness of the first resist film is greater than a film thickness of the second resist film.

11. The pattern forming method according to claim 10, wherein, after the first resist film is formed in the first region on the to-be-processed film, the second resist film is formed in the second region on the to-be-processed film.

12. The pattern forming method according to claim 10, wherein, after the second resist film is formed in the second region on the to-be-processed film, the first resist film is formed in the first region on the to-be-processed film.

13. The pattern forming method according to claim 10, wherein a material of the first resist film differs from a material of the second resist film.

14. The pattern forming method according to claim 1, wherein the physical guide is formed through an imprint process.

15. The pattern forming method according to claim 14, wherein
a template used in the imprint process comprises:
a first convex pattern corresponding to the first predetermined pattern; and
a second convex pattern corresponding to the second predetermined pattern, and
a pattern height of the first convex pattern is greater than a pattern height of the second convex pattern.

16. The pattern forming method according to claim 1, wherein a pattern density of a pattern to be transferred to the to-be-processed film in the first region is lower than a pattern density of a pattern to be transferred to the to-be-processed film in the second region.

17. The pattern forming method according to claim 1, wherein the forming the physical guide comprises:
forming an underlayer film on the to-be-processed film;
forming a first resist pattern in the first region on the underlayer film, the first resist pattern corresponding to the first predetermined pattern;
processing the underlayer film with the first resist pattern serving as a mask, and removing the underlayer film in the second region on the to-be-processed film; and
forming a second resist pattern including the second predetermined pattern in the second region on the to-be-processed film, a thickness of the second resist pattern being smaller than a thickness of the underlayer film.
